(19) United States
(12) Patent Application Publication
(10) Pub. No.: US 2021/0265899 A1
(43) Pub. Date: Aug. 26, 2021

(54) ELECTRICAL DRIVE DEVICE AND ELECTRICAL POWER STEERING DEVICE

(71) Applicant: HITACHI AUTOMOTIVE SYSTEMS, LTD., Hitachinaka-shi, Ibaraki (JP)

(72) Inventors: Narutoshi YAMADA, Hitachinaka-shi, Ibaraki (JP); Takuro KANAZAWA, Hitachinaka-shi, Ibaraki (JP)

(73) Assignee: HITACHI AUTOMOTIVE SYSTEMS, LTD., Hitachinaka-shi, Ibaraki (JP)

(21) Appl. No.: 17/255,631

(22) PCT Filed: Jun. 21, 2019
(86) PCT No.: PCT/JP2019/024623

§ 371 Date: Dec. 23, 2020

(30) Foreign Application Priority Data
Jul. 2, 2018 (JP) 2018-126090

(51) Int. Cl. H02K 11/33; H02K 5/22; H05K 7/14; H02K 7/14; B62D 5/04

(52) U.S. Cl. CPC H02K 11/33; H02K 5/225; B62D 5/0406; H02K 7/14; H05K 7/1427

(57) ABSTRACT

Board supporting body 21A supporting circuit board 18S is provided with first terminal engaging hole 29, and circuit board 18S located so as to be adjacent to board supporting body 21A is provided with second terminal engaging hole 25. First elastic engaging portion 32 elastically engaged with first terminal engaging hole 29, and second elastic engaging portion 33 elastically engaged with second terminal engaging hole 25, are formed at press-fitting type connector terminal 27. Circuit board and board supporting body are fixedly connected together with first and second elastic engaging portions 32, 33 being elastically engaged with first and second terminal engaging holes 29, 25 respectively in a state in which press-fitting type connector terminal 27 is inserted into first and second terminal engaging holes 29, 25. With this, electrical connection of press-fitting type connector terminal and fixing (including direct or indirect fixing) of circuit board can be easily realized.

### TECHNICAL FIELD

The present invention relates to an electrical drive device (an electric drive device) and an electrical power steering device (an electric power steering device), and more particularly to an electric drive device and an electric power steering device each having an electronic control unit.

### BACKGROUND ART

In a field of general industrial equipment, a mechanical control element is driven by an electric motor. In recent years, so-called electrically mechanically integrated electric drive device, which is configured such that an electronic control unit formed from a semiconductor element etc. controlling a rotation speed and/or a rotation torque of the electric motor is integrally mounted in the electric motor, has been used.

As an example of the electrically mechanically integrated electric drive device, for instance, an electric power steering device is configured such that a turning direction and a turning torque of a steering shaft that turns by driver's operation of a steering wheel are detected, and on the basis of these detection values, the electric motor is driven so as to rotate in the same direction as the turning direction of the steering shaft, then a steering assist torque is generated. To control this electric motor, the power steering device is provided with an electronic control unit (ECU).

As a related art electric power steering device, for instance, an electric power steering device disclosed in Japanese Unexamined Patent Application Publication No. 2016-144380 (Patent Document 1) is known. This Patent Document 1 discloses the electric power steering device configured by an electric motor unit and an electronic control unit. An electric motor of the electric motor unit is housed in an accommodation space formed in a motor housing having a cylindrical portion (or a tubular portion) made of aluminum alloy etc. A circuit board, mounting thereon electronic elements or components, of the electronic control unit is housed in an accommodation space formed at an end surface wall portion, located on an opposite side to an output shaft of the electric motor in an axial direction, of the motor housing by a synthetic resin-made or metal-made cover.

The circuit board of the electronic control unit, which is fixed to the end surface wall portion of the motor housing, has a power conversion circuit unit having a power switching element such as a MOSFET and an IGET that drive and control the electric motor, a power supply circuit unit generating power supply voltage and a control circuit unit controlling the power switching element. An output terminal of the power switching element and an input terminal of the electric motor are electrically connected through a bus bar.

The electronic control unit is supplied with power from a battery power supply through a synthetic resin-made connector body. Further, detection signals concerning an operating state etc. are sent to the electronic control unit from detection sensors. The connector body is formed integrally with the cover, and functions as a lid member or a cover member. The connector body is fixed to an outer peripheral surface of the end surface wall portion with an adhesive so as to hermetically cover and seal the electronic control unit. Alternatively, the connector body and the cover could be formed separately, then the connector body is covered by the cover.

Here, a connector terminal that protrudes from the connector body needs connecting to the circuit board of the electronic control unit. In order to simplify this connection, the use of press-fitting type connector terminal has been proposed. For instance, in Japanese Unexamined Patent Application Publication No. 2016-127780 (Patent Document 2), a through hole is formed on the circuit board, and an elastic engaging portion formed at a tip side of the press-fitting type connector terminal is inserted into this through hole, then the circuit board and the press-fitting type connector terminal are electrically connected. With this, only by inserting the connector terminal into the through hole of the circuit board, the electrical connection between the connector terminal and the circuit board can be readily obtained.

As other electric drive devices in which the electronic control unit is integrally mounted, an electric brake and an electric hydraulic pressure controller for various kinds of hydraulic pressure controls are known. In the following explanation, however, as a representative example, the electric power steering device will be explained.

### CITATION LIST

### Patent Document

Patent Document 1: Japanese Unexamined Patent Application Publication No. 2016-144380

Patent Document 2: Japanese Unexamined Patent Application Publication No. 2016-127780

### SUMMARY OF THE INVENTION

### Technical Problem

In a case of the electronic control unit having a configuration as disclosed in Patent Document 2, the metal-made press-fitting type connector terminal that is insert-molded in the synthetic resin-made connector body (the metal-made press-fitting type connector terminal that is formed integrally with the synthetic resin-made connector body by insert-molding) is connected to a power supply (a battery) through a connecting cord. Further, the tip side of this press-fitting type connector terminal is elastically engaged with the through hole provided on the circuit board. Generally, the circuit board and an enclosure are connected to each other with fixing screws. The circuit board is fixed to the enclosure by screwing the fixing screws, and subsequently, the press-fitting type connector terminal is elastically engaged with the through hole of the circuit board.

In a case of this configuration, however, it is necessary to form, on the circuit board, large-diameter penetration holes into which the fixing screws are inserted, and also to form screw holes at the enclosure. This consequently causes problems of increase in size of the circuit board and increase in manufacturing cost due to screwing work. In addition, this inevitably leads to increase in man-hour or machine-hour. Therefore, a technique of realizing the electrical connection of the press-fitting type connector terminal and fixing (including direct fixing and indirect fixing) of the circuit board by a simple configuration or structure has been required for this kind of electric drive device.

An object of the present invention is therefore to provide a new electric drive device and a new electric power steering device that are capable of easily achieving the electrical connection of the press-fitting type connector terminal and the fixing (including the direct fixing and the indirect fixing) of the circuit board.

### Solution to Problem

As a first structural feature of the present invention, a circuit board is provided with a first terminal engaging hole, and a board supporting body located so as to be adjacent to the circuit board and supporting the circuit board is provided with a second terminal engaging hole. A first elastic engaging portion that is elastically engaged with the first terminal engaging hole, and a second elastic engaging portion that is adjacent to the first elastic engaging portion and elastically engaged with the second terminal engaging hole, are formed at a press-fitting type connector terminal. Then, the circuit board and the board supporting body are fixedly connected together with the first and second elastic engaging portions being elastically engaged with the first and second terminal engaging holes respectively in a state in which the press-fitting type connector terminal is inserted into the first and second terminal engaging holes.

As a second structural feature of the present invention, a board supporting body supporting a circuit board is provided with a first terminal engaging hole, and the fixing portion located so as to be adjacent to the board supporting body is provided with a second terminal engaging hole. A first elastic engaging portion that is elastically engaged with the first terminal engaging hole, and a second elastic engaging portion that is adjacent to the first elastic engaging portion and elastically engaged with the second terminal engaging hole, are formed at a press-fitting type connector terminal. Then, the board supporting body and the fixing portion are fixedly connected together with the first and second elastic engaging portions being elastically engaged with the first and second terminal engaging holes respectively in a state in which the press-fitting type connector terminal is inserted into the first and second terminal engaging holes.

### Effects of Invention

According to the present invention, the circuit board and the board supporting body can be fixed together by the press-fitting type connector terminal, and the enclosure and the board supporting body can be fixed together by the press-fitting type connector terminal. It is therefore possible to realize the electrical connection of the press-fitting type connector terminal and the indirect or direct fixing of the circuit board by the simple configuration or structure.

### BRIEF DESCRIPTION OF THE DRAWINGS

FIG. 1 is a general perspective view of a steering device as an example to which the present invention is applied.

FIG. 2 is a perspective view of an electronic control unit of an electric power steering device shown in FIG. 1.

FIG. 3 is a sectional view for explaining a fixing manner of a circuit board and a board supporting body of the electric power steering device shown in FIG. 2.

FIG. 4 is an enlarged sectional view of an A-part indicated in the electric power steering device shown in FIG. 3.

FIG. 5 is a sectional view for explaining a fixing manner of an enclosure and a board supporting body of the electric power steering device shown in FIG. 2.

FIG. 6 is an enlarged sectional view of a B-part indicated in the electric power steering device shown in FIG. 5.

### EMBODIMENTS FOR CARRYING OUT THE INVENTION

An embodiment of the present invention will be explained in detail below with reference to the drawings. The present invention is not limited to the following embodiment, and includes all design modifications and equivalents belonging to the technical scope of the present invention.

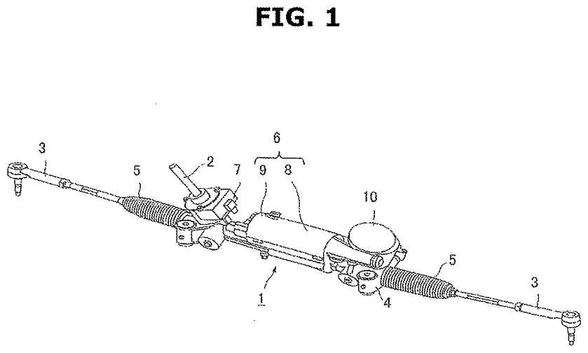

Before explaining the embodiment of the present invention, a configuration of a steering device as an example to which the present invention is applied will be briefly explained using FIG. 1.

First, a steering device to steer front wheels of a vehicle will be explained. A steering device 1 is configured as shown in FIG. 1. A pinion (not shown) is provided at a lower end of a steering shaft 2 connecting to a steering wheel (not shown). This pinion is engaged with a rack (not shown) that extends in right and left directions of a vehicle body. A tie rod 3 to steer the front wheels in the right and left directions is each connected to both ends of the rack. The rack is accommodated in a rack housing 4. Between the rack housing 4 and each tie rod 3, a rubber boot 5 is provided.

The steering device 1 is provided with an electric power steering device 6 to assist torque when performing a turning operation of the steering wheel. That is, a torque sensor 7 that detects a turning direction and a turning torque of the steering shaft 2 is provided. And, an electric motor unit 8 that provides a steering assistive force to the rack via a gear 10 on the basis of a detection value of the torque sensor 7 is provided. Further, an electronic control unit (ECU) 9 that controls an electric motor disposed in the electric motor unit 8 is provided. The electric motor unit 8 of the electric power steering device 6 is connected to the gear 10 at three portions of an outer periphery at an output shaft side of the electric motor unit 8 with screws (not shown). The electronic control unit 9 is disposed on an opposite side to the output shaft side of the electric motor unit 8.

In the electric power steering device 6, when the steering shaft 2 is turned in any turning direction by the steering wheel operation, the torque sensor 7 detects the turning direction and the turning torque of the steering shaft 2. The electronic control unit 9 calculates a drive operation amount of the electric motor on the basis of these detection values. The electric motor is then driven by a power switching element of the electronic control unit 9 on the basis of the calculated drive operation amount. And, an output shaft of the electric motor rotates so as to drive and rotate the steering shaft 2 in the same direction as a direction of the steering wheel operation. This rotation of the output shaft of the electric motor is transmitted to the rack (not shown) through the pinion (not shown) and the gear 10, and the vehicle is steered. Since such configuration and workings are well known, a further explanation will be omitted here.

As mentioned above, in the case of the electronic control unit having the configuration as disclosed in Patent Document 2, the tip of the metal-made press-fitting type connector terminal insert-molded in the synthetic resin-made connector body (the tip of the metal-made press-fitting type connector terminal formed integrally with the synthetic resin-made connector body by insert-molding) is elastically engaged with and fixed to the through hole provided on the circuit board. Further, the circuit board and the enclosure are generally connected to each other with fixing screws. Then, the circuit board is fixed to the enclosure by screwing the fixing screws, and subsequently, the press-fitting type connector terminal is elastically engaged with and fixed to the through hole of the circuit board.

In the case of this configuration, however, it is necessary to form, on the circuit board, the large-diameter penetration holes into which the fixing screws are inserted, and also to form the screw holes at the enclosure. This consequently causes the problems of increase in size of the circuit board and increase in manufacturing cost due to screwing work.

From such background, the embodiment of the present invention proposes an electric power steering device having the following configuration.

In the embodiment, a circuit board is provided with a first terminal engaging hole, and a board supporting body located so as to be adjacent to the circuit board and supporting the circuit board is provided with a second terminal engaging hole. A first elastic engaging portion that is elastically engaged with the first terminal engaging hole, and a second elastic engaging portion that is adjacent to the first elastic engaging portion and elastically engaged with the second terminal engaging hole, are formed at a press-fitting type connector terminal. Then, the circuit board and the board supporting body are fixedly connected together with the first and second elastic engaging portions being elastically engaged with the first and second terminal engaging holes respectively in a state in which the press-fitting type connector terminal is inserted into the first and second terminal engaging holes.

In the embodiment, a board supporting body supporting a circuit board is provided with a first terminal engaging hole, and the fixing portion located so as to be adjacent to the board supporting body is provided with a second terminal engaging hole. A first elastic engaging portion that is elastically engaged with the first terminal engaging hole, and a second elastic engaging portion that is adjacent to the first elastic engaging portion and elastically engaged with the second terminal engaging hole, are formed at a press-fitting type connector terminal. Then, the board supporting body and the fixing portion are fixedly connected together with the first and second elastic engaging portions being elastically engaged with the first and second terminal engaging holes respectively in a state in which the press-fitting type connector terminal is inserted into the first and second terminal engaging holes.

According to such embodiment, the circuit board and the board supporting body can be fixed together by the press-fitting type connector terminal, and the enclosure and the board supporting body can be fixed together by the press-fitting type connector terminal. It is therefore possible to realize the electrical connection of the press-fitting type connector terminal and the indirect or direct fixing of the circuit board by the simple configuration or structure.

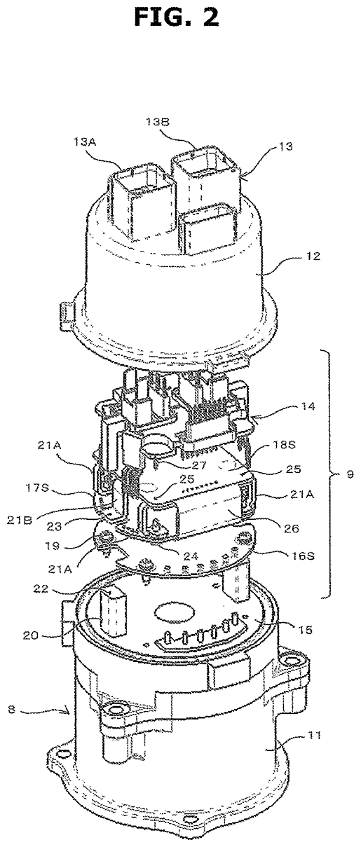

Next, a configuration of the electric power steering device according to the embodiment of the present invention will be explained in detail with reference to FIGS. 2 to 6.

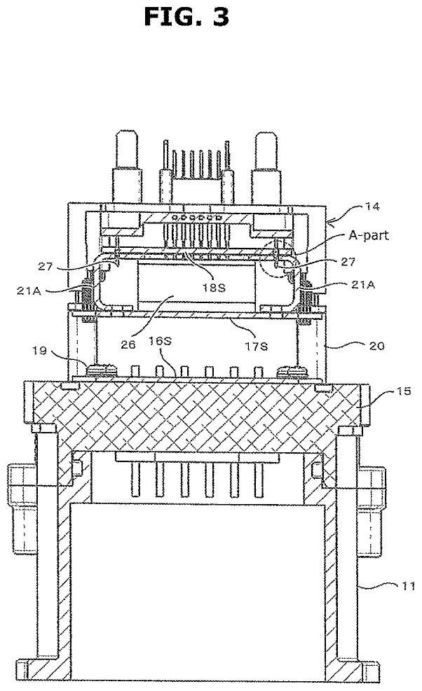

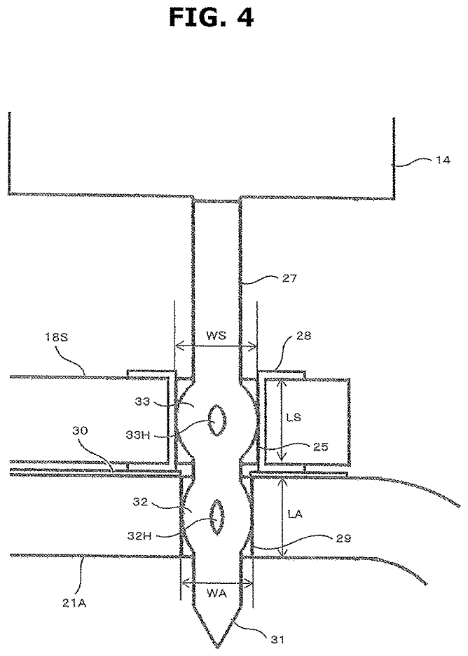

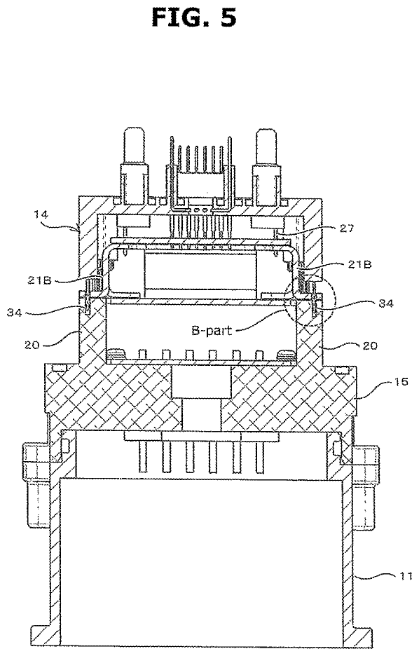

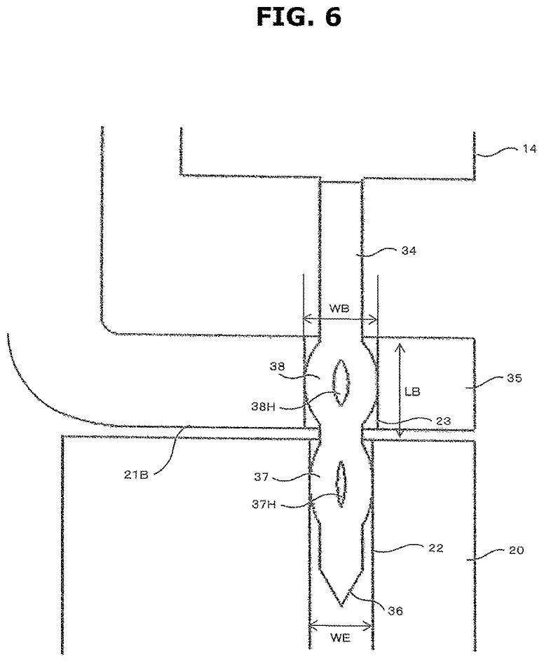

FIG. 2 is a drawing, viewed from an oblique direction, with the electronic control unit of the electric power steering device dismantled. FIGS. 3 and 4 illustrate cross sections of a fixing part of the circuit board and the board supporting body. FIGS. 5 and 6 illustrate cross sections of a fixing part of the enclosure and the board supporting body. Here, FIGS. 3 and 4 show an example in which the circuit board is directly supported by the board supporting body. FIGS. 5 and 6 show an example in which the circuit board is indirectly supported by the enclosure through the board supporting body.

As shown in FIG. 2, the electric motor unit 8 forming the electric power steering device is configured by a motor housing 11 having a cylindrical portion (or a tubular portion) made of aluminum or aluminum-based metal such as aluminum alloy and the electric motor (not shown) accommodated in the motor housing 11. As is well known, the electric motor has a rotation shaft, and a pinion (not shown) is fixed to an output portion of this rotation shaft, then rotational motion is transmitted to the rack (not shown). A shaft center of the rotation shaft and an axial center of the motor housing 11 are substantially coaxially aligned with each other, and the electric motor can rotate in the motor housing 11.

The electronic control unit 9 is located at an opposite side to the output portion (the pinion side) in the axial direction of the motor housing 11. The electronic control unit 9 is covered with a closed-bottomed tubular cover (so-called cup-shaped cover) 12 (made of synthetic resin or metal) so as to be accommodated in the cover 12. With this, the electronic control unit 9 has a liquid-tight structure. The cover 12 is provided with a socket part 13 at an opposite side to the motor housing 11.

The socket part 13 is provided with a power supply side sockets 13A and 13B that are connected to a power supply (a battery) and a sensor/network side socket that is connected to the sensors such as a steering angle sensor and CAN network. The power supply side sockets 13A and 13B are a pair of sockets (i.e. two sockets), and these sockets are sockets for forming a redundant system (a dual-redundancy system). The redundant system will be mentioned later.

Next, a configuration of the electronic control unit 9 will be explained. In FIG. 2, the motor housing 11 is made of aluminum alloy, and acts as a heat sink that radiates or releases heat generated at the electric motor and heat generated in after-mentioned power supply circuit unit and power conversion circuit unit to the outside atmosphere. The electric motor and the motor housing 11 form the electric motor unit 8.

The electronic control unit 9 is connected to an end surface wall portion 15 of the motor housing 11 which is an opposite side to the pinion of the electric motor unit 8. Here, the end surface wall portion 15 acts as an enclosure to which the electronic control unit 9 is fixed. The electronic control unit 9 has a power conversion circuit board 16S mounting thereon a power conversion circuit unit, a power supply circuit board 17S mounting thereon a power supply circuit unit, a control circuit board 18S mounting thereon a control circuit unit and a connector body 14.

These circuit boards 16S, 17S and 18S are assembled in a stacked state so as to be parallel to each other. Here, electronic components and electrical components forming each of the circuit units of the power conversion circuit board 16S, the power supply circuit board 17S and the control circuit board 18S are not illustrated in the drawings.

Regarding the end surface wall portion 15 of the motor housing 11, the end surface wall portion 15 is formed separately, and the end surface wall portion 15 is fixedly connected to the motor housing 11 with screws or by welding. However, the motor housing 11 and the end surface wall portion 15 could be formed integrally with each other by casting or cutting.

Here, the power conversion circuit unit, the power supply circuit unit and the control circuit unit form the redundant system (the dual-redundancy system) by a first electronic control unit and a second electronic control unit. In a normal condition, the electric motor is driven and controlled by the first electronic control unit. However, if an abnormal condition or a failure occurs at the first electronic control unit, the control is switched to the second electronic control unit, and the electric motor is driven and controlled by the second electronic control unit.

Therefore, normally, heat from the first electronic control unit is transmitted to the motor housing 11. If the abnormal condition or the failure occurs at the first electronic control unit, the first electronic control unit stops and the second electronic control unit operates, then heat from the second electronic control unit is transmitted to the motor housing 11.

Further, both of the first electronic control unit and the second electronic control unit could operate as a regular electronic control unit. And, if the abnormal condition or the failure occurs at one of the electronic control units, the other electronic control unit drives and controls the electric motor by half ability. In this case, although capability of the electric motor is half, so-called power steering function is secured. Therefore, in the normal condition, heat from the first electronic control unit and the second electronic control unit is transmitted to the motor housing 11. In the present embodiment, the latter redundant system is applied, and thus the pair of power supply side sockets 13A and 13B are provided.

As illustrated in FIG. 2, the electronic control unit 9 is configured by the power conversion circuit board 16S, the power supply circuit board 17S, the control circuit board 18S and the connector body 14. And, the power conversion circuit board 16S, the power supply circuit board 17S, board supporting bodies 21A and 21B, the control circuit board 18S and the connector body 14 are arranged in a stacked state in this order from the end surface wall portion 15 side to a direction moving away from the end surface wall portion 15.

The control circuit unit mounted on the control circuit board 18S has the function of generating a control signal for driving a switching element (MOSFET) of the Power conversion circuit board 16S, and is configured by a microcomputer, a peripheral circuit and so on.

The power supply circuit unit mounted on the power supply circuit board 17S has the function of generating power supply voltage to drive the control circuit unit mounted on the control circuit board 18S and power supply voltage to drive the power conversion circuit unit mounted on the power conversion circuit board 16S, and is configured by a capacitor, a coil, a switching element and so on.

The power conversion circuit unit mounted on the power conversion circuit board 16S has the function of controlling power (current) flowing in a motor winding of the electric motor, and is configured by a switching element that forms three-phase upper and lower arms and so on.

A unit having a large heat value in the electronic control unit 9 is mainly the power conversion circuit unit and the power supply circuit unit. Heat of the power conversion circuit unit and the power supply circuit unit is released mainly from the motor housing 11 made of aluminum alloy.

The connector body 14 made of synthetic resin is arranged between the control circuit board 18S and the cover 12, and is connected to a vehicle power supply (the battery) and other external control devices (not shown). Needless to say, this connector body 14 is electrically connected to the power conversion circuit board 16S, the power supply circuit board 17S and the control circuit board 18S.

The cover 12 has the function of accommodating and liquid-tightly sealing the power conversion circuit board 16S, the power supply circuit board 17S and the control circuit board 18S. In the present embodiment, the cover 12 is fixed to the motor housing 11.

The power conversion circuit board 16S forming the power conversion circuit unit is provided on a surface of the end surface wall portion 15 of the motor housing 11. The switching element etc. are mounted on a surface of the power conversion circuit board 16S. The power conversion circuit board 16S is fixed to the end surface wall portion 15 with four fixing screws 19.

Here, it is desirable to form the power conversion circuit board 16S by a metal board, which can release heat generated at the switching element etc. to the end surface wall portion 15 efficiently. However, the power conversion circuit board 16S could be formed by a glass epoxy board. In the present embodiment, the power conversion circuit board 16S is formed by the glass epoxy board.

On the surface at an outer peripheral side of the end surface wall portion 15 of the motor housing 11, protruding fixing portions 20 acting as a part of the enclosure that extends to the direction moving away from the end surface wall portion 15 in the direction of the rotation shaft of the electric motor are formed. The protruding fixing portion 20 functions as the electrical earth. The protruding fixing portions 20 are arranged at angles of 180° so as to face each other.

The protruding fixing portion 20 has the function of fixing the board supporting body 21B made of conductive metal and having the function of fixing the circuit board. Further, a space formed by the protruding fixing portions 20 has the function of accommodating the switching element etc. forming the power conversion circuit unit. Each protruding fixing portion 20 is provided, at its upper surface side, with a terminal engaging hole 22 into which an after-mentioned press-fitting type connector terminal 34 is inserted.

The power supply circuit board 17S is formed by a glass epoxy board. Board supporting bodies 21A are fixed to the power supply circuit board 17S at four corners of the power supply circuit board 17S with fixing screws. Further, a pair of cutting parts, which are cut inwards in a radial direction and face each other, are formed at the power supply circuit board 17S. The cutting part has the function of accommodating one side of the board supporting body 215. The board supporting body 21B is provided with a terminal engaging hole 23 into which the after-mentioned press-fitting type connector terminal 34 is inserted.

The power conversion circuit board 16S and the power supply circuit board 17S are connected by flexible connectors. The flexible connector is a connector that can be curved or bent freely, and can connect the power conversion circuit board 16S and the power supply circuit board 17S with these power conversion circuit board 16S and power supply circuit board 17S arranged parallel to each other.

The board supporting bodies 21A made of conductive metal are fixed to the power supply circuit board 17S at the four corners of the power supply circuit board 17S with the fixing screws 24, and also on an opposite side, the board supporting bodies 21A are fixed to the control circuit board 18S at four corners of the control circuit board 18S. The control circuit board 18S is provided with terminal engaging holes 25 into which after-mentioned press-fitting type connector terminals 27 are inserted respectively. Also, each board supporting body 21A is provided, at the control circuit board 18S side thereof, with a terminal engaging hole 29 (see FIG. 4) into which the after-mentioned press-fitting type connector terminal 27 is inserted.

Although a detailed explanation will be given later, the board supporting body 21A is shaped into a square bracket “]”, and one side of the board supporting body 21A is fixed to the power supply circuit board 17S with the fixing screw 24, and the other side of the board supporting body 21A is fixed to the control circuit board 18S with the press-fitting type connector terminal 27. On the other hand, the board supporting body 21B is shaped like a letter “S”, and one side of the board supporting body 21B is fixed to the protruding fixing portion 20 with the press-fitting type connector terminal 34, and the other side of the board supporting body 21B contacts the control circuit board 18S and is fixed to the control circuit board 18S with, e.g. an adhesive and supports the control circuit board 18S. Each of the board supporting bodies 21B is arranged between the board supporting bodies 21A, and suppresses warp of the control circuit board 18S at the middle of the control circuit board 18S, thereby improving reliability of the control circuit board 18S.

The electronic components and the electrical components that form the power supply circuit mounted on the power supply circuit board 17S are accommodated in a space formed by the board supporting bodies 21A and the board supporting bodies 21B. Since the space formed by the board supporting bodies 21A and the board supporting bodies 21B is open, heat generated at the power supply circuit mounted on the power supply circuit board 17S can be released efficiently.

The control circuit board 18S is formed by a glass epoxy board. Just as the power conversion circuit board 16S and the power supply circuit board 17S are connected by the flexible connectors, the power supply circuit board 17S and the control circuit board 18S are connected by flexible connectors 26.

The connector body 14 is located above or over the control circuit board 18S. The connector body 14 is made of synthetic resin, and the press-fitting type connector terminals are embedded in the connector body 14 by insert-molding. The press-fitting type connector terminals are formed by a power supply side connector terminal connected to the power supply, a sensor/network side connector terminal connected to the steering angle sensor, a rotation sensor and the CAN network, an earth terminal and so on. Here, since the electronic control unit 9 forms the redundant system, the power supply side connector terminal also forms the redundant system.

The connector body 14 has, at four corners thereof, stepped parts, and the press-fitting type connector terminals 27 are embedded in these four corners respectively. A part of each press-fitting type connector terminal 27 is exposed to the outside.

The press-fitting type connector terminal 27 has a flat plate shape, and has two elastic engaging portions 33 and 32 at a tip side of the press-fitting type connector terminal 27. The two elastic engaging portions 33 and 32 are elastically engaged with the terminal engaging hole 25 formed on the control circuit board 18S and the terminal engaging hole 29 (see FIG. 4) formed at the other side of the board supporting body 21A respectively. Likewise, the press-fitting type connector terminal 34 is elastically engaged with the terminal engaging hole 23 formed at the board supporting body 21B and the terminal engaging hole 22 formed at the protruding fixing portion 20.

Next, a configuration around the press-fitting type connector terminal 27 will be explained in detail. FIG. 3 is a sectional view of the electric power steering device, cut by a plane passing through the board supporting bodies 21A in the axial direction. The press-fitting type connector terminal 27 is the earth terminal for connecting the electronic components and the electrical components mounted on the control circuit board 18S with the earth.

This press-fitting type connector terminal 27 is connected to the after-mentioned press-fitting type connector terminal 34 shown in FIGS. 5 and 6, and this connection is established in the connector body 14. More specifically, the press-fitting type connector terminal 27 and the press-fitting type connector terminal 34 are formed integrally with each other by stamping. Since these press-fitting type connector terminal 27 and press-fitting type connector terminal 34 are required to have a mechanical fixing function, their thicknesses are determined to satisfy the fixing function.

The control circuit board 18S is located so as to be adjacent to the board supporting bodies 21A when viewed from the axial direction of the motor housing 11, and positions of the control circuit board 18S and the board supporting bodies 21A are set so that the terminal engaging hole 25 of the control circuit board 18S and the terminal engaging hole 29 (see FIG. 4) of the board supporting body 21A overlap each other or are aligned with each other. Then, the press-fitting type connector terminal 27 is inserted into the terminal engaging holes 25 and 29, and the elastic engaging portions 33 and 32 of the press-fitting type connector terminal 27 are engaged with the terminal engaging holes 25 and 29. With this, the control circuit board 18S and each board supporting bodies 21A are mechanically fixed together, and each press-fitting type connector terminal 27 and the control circuit board 18S are electrically connected.

FIG. 4 is an enlarged sectional view of an A-part of FIG. 3. In FIG. 4, the terminal engaging hole 25 acting as a through hole is formed on the control circuit board 18S formed by the glass epoxy board. The terminal engaging hole 25 is provided with a land portion 28 made of conductive metal, and this land portion 28 is connected to the electronic components (not shown) and the electrical components (not shown).

Likewise, the terminal engaging hole 29 is formed at the metal-made board supporting bodies 21A. Center lines of the terminal engaging hole 25 and the terminal engaging hole 29 are coaxially aligned with each other, thereby smoothly inserting the press-fitting type connector terminal 27 into these terminal engaging hole 25 and terminal engaging hole 29. It is noted that a diameter of the terminal engaging hole 29 of the board supporting body 21A is set to be smaller than that of the terminal engaging hole 25 of the control circuit board 18S. This reason will be explained later.

Between the control circuit board 18S and the board supporting body 21A, an insulating sheet 30 is interposed to electrically insulate the control circuit board 18S and the board supporting body 21A from each other. However if there is a sufficient gap between the control circuit board 18S and the board supporting body 21A, the insulating sheet 30 is not necessarily needed.

The press-fitting type connector terminal 27 establishing electrical conduction between the control circuit board 18S and the board supporting body 21A is inserted into the terminal engaging holes 25 and 29. The press-fitting type connector terminal 27 is shaped into the long narrow flat plate, and has a pointed portion (or a sharp-edged portion) 31 formed into a sharp-edged shape at the tip side of the press-fitting type connector terminal 27.

When viewing the press-fitting type connector terminal 27 from this sharp-edged portion 31, the supporting body-side elastic engaging portion 32 whose width is wider and the board-side elastic engaging portion 33 whose width is also wider are formed from the tip side of the press-fitting type connector terminal 27. The supporting body-side elastic engaging portion 32 is elastically engaged with the terminal engaging hole 29 of the board supporting body 21A, and the board-side elastic engaging portion 33 is elastically engaged with the terminal engaging hole 25 of the control circuit board 18S.

Both the elastic engaging portions 33 and 32 are also formed so as to be adjacent to each other according to the arrangement positions of the control circuit board 18S and the board supporting bodies 21A. Therefore, a distance between the control circuit board 18S and the board supporting bodies 21A becomes short, then bending moment mutually acting on the elastic engaging portions 32 and 33 does not become large, thereby improving reliability of the mechanical fixing function.

The elastic engaging portions 32 and 33 have, at middle portions thereof, openings 32H and 33H respectively. Sections of these openings 32H and 33H are elastically deformed, and give an elastic force in a direction orthogonal to an inserting direction of the press-fitting type connector terminal 27. With this, a predetermined supporting force (mainly, a frictional force) can be obtained between the elastic engaging portion 33 and the terminal engaging hole 25 and between the elastic engaging portion 32 and the terminal engaging hole 29.

Here, a width WA of the supporting body-side elastic engaging portion 32 is set to a width according to the terminal engaging hole 29 of the board supporting body 21A. Also, a width WS of the board-side elastic engaging portion 33 is set to a width according to the terminal engaging hole 25 of the control circuit board 18S. That is, the widths WA and WS of the elastic engaging portions 32 and 33 are determined so as to be able to obtain the predetermined supporting force (mainly, the frictional force) when the elastic engaging portions 32 and 33 are elastically engaged with the terminal engaging holes 29 and 25 respectively.

As mentioned above, the diameter of the terminal engaging hole 29 of the board supporting body 21A is set to be smaller than that of the terminal engaging hole 25 of the control circuit board 18S. This reason is as follows. That is, when inserting the press-fitting type connector terminal 27 from the control circuit board 18S side, first the supporting body-side elastic engaging portion 32 of the press-fitting type connector terminal 27 is inserted into the terminal engaging hole 25 of the control circuit board 18S.

Therefore, if the terminal engaging hole 25 is set to be smaller, since the supporting body-side elastic engaging portion 32 of the press-fitting type connector terminal 27 has the large width WA, the supporting body-side elastic engaging portion 32 cannot properly be inserted into the terminal engaging hole 25. As a matter of course, when inserting the press-fitting type connector terminal 27 from the board supporting body 21A side, an opposite relationship is established.

A length of the board-side elastic engaging portion 33 is determined according to an axial direction length LS of the terminal engaging hole 25 of the control circuit board 18S. Likewise, a length of the supporting body-side elastic engaging portion 32 is determined according to an axial direction length LA of the terminal engaging hole 29 of the board supporting body 21A. Therefore, in order to increase the supporting force, the lengths LS and LA of the terminal engaging holes 25 and 29 are set to be longer, and the lengths of the elastic engaging portions 33 and 32 are set to be longer.

With such configuration, if the press-fitting type connector terminal 27 serves as the earth terminal, an earth circuit is established from an earth terminal of the control circuit board 18S toward the after-mentioned press-fitting type connector terminal 34 through the land portion 28 and the board-side elastic engaging portion 33.

The board supporting body 21A and the supporting body-side elastic engaging portion 32 are elastically engaged with each other and fixed together, and the control circuit board 18S and the board-side elastic engaging portion 33 are elastically engaged with each other and fixed together. It is therefore possible to fix the control circuit board 18S to the board supporting body 21A without using a fixing screw etc. Further, since the press-fitting type connector terminal 27 is only inserted into the terminal engaging holes 25 and 29 of the control circuit board 18S and the board supporting body 21A, it is possible to reduce man-hour or machine-hour needed to form the fixing screw etc.

Here, in the present embodiment, the press-fitting type connector terminal 27 is used as the earth terminal. However, as a matter of course, the press-fitting type connector terminal 27 can be used only for fixing the control circuit board 18S and the board supporting body 21A without carrying electric current.

Further, in a case where the control circuit board 18S is replaced with the power supply circuit board 17S, only the press-fitting type connector terminal 27 is used, and the press-fitting type connector terminal 27 could act as the power supply connector terminal. The electric current from the power supply is supplied to the power supply circuit of the power supply circuit board 17S through the press-fitting type connector terminal 27, and the board supporting body 21A and the power supply circuit board 17S are fixed together by the press-fitting type connector terminal 27.

Also in this case, the board supporting body 21A and the supporting body-side elastic engaging portion 32 are elastically engaged with each other and fixed together, and the power supply circuit board 17S and the board-side elastic engaging portion 33 are elastically engaged with each other and fixed together. It is therefore possible to fix the power supply circuit board 17S to the board supporting body 21A without using a fixing screw etc. Further, since the press-fitting type connector terminal 27 is only inserted into the terminal engaging holes of the power supply circuit board 17S and the board supporting body 21A, it is possible to reduce man-hour or machine-hour needed to form the fixing screw etc.

Next, a configuration around the other press-fitting type connector terminal 34 will be explained in detail. FIG. 5 is a sectional view of the electric power steering device, cut by a plane passing through the board supporting body 21B in the axial direction. The press-fitting type connector terminal 34 is the earth terminal for connecting the electronic components and the electrical components mounted on the control circuit board 18S to the protruding fixing portion 20 for the earth.

In this case, as described above, the press-fitting type connector terminal 27 shown in FIG. 3 and the press-fitting type connector terminal 34 are connected in the connector body 14.

A bending fixing portion 35 of the board supporting body 21B is arranged so as to be adjacent to the protruding fixing portion 20 acting as the enclosure, and positions of the board supporting body 21B and the protruding fixing portion 20 are determined so that the terminal engaging hole 23 of the board supporting body 21B and the terminal engaging hole 22 of the protruding fixing portion 20 overlap each other or are aligned with each other.

Then, the press-fitting type connector terminal 34 is inserted into the terminal engaging holes 23 and 22, and elastic engaging portions 38 and 37 of the press-fitting type connector terminal 34 are engaged with the terminal engaging holes 23 and 22. With this, the board supporting body 21B and the protruding fixing portion 20 are mechanically fixed together, and the press-fitting type connector terminal 34 and the protruding fixing portion 20 are electrically connected. Here, the protruding fixing portion 20 is connected to the motor housing 11 for the earth.

FIG. 6 is an enlarged sectional view of a B-part of FIG. 5. In FIG. 6, the terminal engaging hole 23 is formed at the bending fixing portion 35 of the metal-made board supporting body 21B. Likewise, the terminal engaging hole 22 is formed at the conductive metal-made protruding fixing portion 20. Center lines of the terminal engaging hole 23 and the terminal engaging hole 22 are coaxially aligned with each other, thereby smoothly inserting the press-fitting type connector terminal 34 into these terminal engaging hole 23 and terminal engaging hole 22. It is noted that a diameter of the terminal engaging hole 22 of the protruding fixing portion 20 is set to be smaller than that of the terminal engaging hole 23 of the board supporting body 21B. This reason will be explained later.

The press-fitting type connector terminal 34 mechanically fixing the board supporting body 21B and the protruding fixing portion 20 and establishing electrical conduction with the protruding fixing portion 20 is inserted into the terminal engaging holes 23 and 22. The press-fitting type connector terminal 34 is shaped into a long narrow flat plate, and has a pointed portion (or a sharp-edged portion) 36 formed into a sharp-edged shape at a tip side of the press-fitting type connector terminal 34.

When viewing the press-fitting type connector terminal 34 from this sharp-edged portion 36, the fixing portion-side elastic engaging portion 37 and the supporting body-side elastic engaging portion 38 are formed from the tip side of the press-fitting type connector terminal 34. The fixing portion-side elastic engaging portion 37 is elastically engaged with the terminal engaging hole 22 of the protruding fixing portion 20, and the supporting body-side elastic engaging portion 38 is elastically engaged with the terminal engaging hole 23 of the board supporting body 21B.

Both the elastic engaging portions 37 and 38 are also formed so as to be adjacent to each other according to the arrangement positions of the protruding fixing portion 20 and the board supporting body 21B. Therefore, a distance between the protruding fixing portion 20 and the board supporting body 21B becomes short, then bending moment mutually acting on the elastic engaging portions 37 and 38 does not become large, thereby improving reliability of the mechanical fixing function.

The elastic engaging portions 37 and 38 have, at middle portions thereof, openings 37H and 38H respectively. Sections of these openings 37H and 38H are elastically deformed, and give an elastic force in a direction orthogonal to an inserting direction of the press-fitting type connector terminal 34. With this, a predetermined supporting force (mainly, a frictional force) can be obtained between the elastic engaging portion 37 and the terminal engaging hole 22 and between the elastic engaging portion 38 and the terminal engaging hole 23.

Here, a width WE of the fixing portion-side elastic engaging portion 37 is set to a width according to the terminal engaging hole 22 of the protruding fixing portion 20. Also, a width WB of the supporting body-side elastic engaging portion 38 is set to a width according to the terminal engaging hole 23 of the board supporting body 21B. That is, the widths WE and WB of the elastic engaging portions 37 and 38 are determined so as to be able to obtain the predetermined supporting force (mainly, the frictional force) when the elastic engaging portions 37 and 38 are elastically engaged with the terminal engaging holes 22 and 23 respectively.

As mentioned above, the diameter of the terminal engaging hole 22 of the protruding fixing portion 20 is set to be smaller than that of the terminal engaging hole 23 of the board supporting body 21B. This reason is as follows. That is, when inserting the press-fitting type connector terminal 34 from the board supporting body 21B side, first the fixing portion-side elastic engaging portion 37 of the press-fitting type connector terminal 34 is inserted into the terminal engaging hole 23 of the board supporting body 21B. Therefore, if the terminal engaging hole 23 is set to be smaller, since the fixing portion-side elastic engaging portion 37 of the press-fitting type connector terminal 34 has the large width WE, the fixing portion-side elastic engaging portion 37 cannot properly be inserted into the terminal engaging hole 23.

A length of the supporting body-side elastic engaging portion 38 is determined according to an axial direction length LB of the terminal engaging hole 23 of the board supporting body 21B. Likewise, a length of the fixing portion-side elastic engaging portion 37 is determined according to an axial direction length of the terminal engaging hole 22 of the protruding fixing portion 20. Here, the length of the fixing portion-side elastic engaging portion 37 can be arbitrarily determined within a range of a length of the protruding fixing portion 20. In order to increase the supporting force, the lengths of the terminal engaging holes 22 and 23 are set to be longer, and the lengths of the elastic engaging portions 37 and 38 are set to be longer.

With such configuration, if the press-fitting type connector terminal 34 serves as the earth terminal, an earth circuit is established from the press-fitting type connector terminal 34 to the protruding fixing portion 20 through the fixing portion-side elastic engaging portion 37. The protruding fixing portion 20 and the fixing portion-side elastic engaging portion 37 are elastically engaged with each other and fixed together, and the board supporting body 21B and the supporting body-side elastic engaging portion 38 are elastically engaged with each other and fixed together. It is therefore possible to fix the board supporting body 21B to the protruding fixing portion 20 without using a fixing screw etc.

Further, since the press-fitting type connector terminal 34 is only inserted into the terminal engaging holes 23 and 22 of the board supporting body 21B and the protruding fixing portion 20, it is possible to reduce man-hour or machine-hour needed to form the fixing screw etc. Here, in the present embodiment, the press-fitting type connector terminal 34 is used as the earth terminal. However, as a matter of course, the press-fitting type connector terminal 34 can be used only for fixing the board supporting body 21B and the protruding fixing portion 20 without carrying electric current.

In the above embodiment, a configuration in which the board supporting body 21A and the board supporting body 21B are separately formed is explained. However, the board supporting body 21A and the board supporting body 21B could be formed integrally with each other or fixedly connected to each other as an annular board supporting body, then a space formed in this board supporting body accommodates therein the electronic components and the electrical components forming the power supply circuit.

In this case, the control circuit board is arranged at an upper surface side of the annular board supporting body and fixed to the annular board supporting body by the press-fitting type connector terminals, and the power supply circuit board is arranged at a lower surface side of the annular board supporting body and fixed to the annular board supporting body with the fixing screws, then the annular board supporting body and the protruding fixing portions are fixed together by the press-fitting type connector terminals.

As described above, according to the present invention, the circuit board is provided with the first terminal engaging hole, and the board supporting body located so as to be adjacent to the circuit board and supporting the circuit board is provided with the second terminal engaging hole. The first elastic engaging portion that is elastically engaged with the first terminal engaging hole, and the second elastic engaging portion that is adjacent to the first elastic engaging portion and elastically engaged with the second terminal engaging hole, are formed at the press-fitting type connector terminal. Then, the circuit board and the board supporting body are fixedly connected together with the first and second elastic engaging portions being elastically engaged with the first and second terminal engaging holes respectively in a state in which the press-fitting type connector terminal is inserted into the first and second terminal engaging holes.

Further, according to the present invention, the board supporting body supporting the circuit board is provided with the first terminal engaging hole, and the fixing portion located so as to be adjacent to the board supporting body is provided with the second terminal engaging hole. The first elastic engaging portion that is elastically engaged with the first terminal engaging hole, and the second elastic engaging portion that is adjacent to the first elastic engaging portion and elastically engaged with the second terminal engaging hole, are formed at the press-fitting type connector terminal. Then, the board supporting body and the fixing portion are fixedly connected together with the first and second elastic engaging portions being elastically engaged with the first and second terminal engaging holes respectively in a state in which the press-fitting type connector terminal is inserted into the first and second terminal engaging holes.

According to the present invention, the circuit board and the board supporting body can be fixed together by the press-fitting type connector terminal, and the enclosure and the board supporting body can be fixed together by the press-fitting type connector terminal. It is therefore possible to realize the electrical connection of the press-fitting type connector terminal and the indirect or direct fixing of the circuit board by the simple configuration or structure.

The present invention is not limited to the above embodiment, and includes all design modifications. The above embodiment is an embodiment that is explained in detail to easily understand the present invention, and the present invention is not necessarily limited to the embodiment having all elements or components described above. Further, a part of the configuration of the embodiment can be replaced with a configuration of other embodiments. Also, the configuration of other embodiments could be added to the configuration of the embodiment. Moreover, regarding a part of the configuration of the embodiment, the configuration of other embodiments could be added, removed and replaced.

### EXPLANATION OF REFERENCE

6 . . . electric power steering device, 8 . . . electric motor unit, 9 . . . electronic control unit, 11 . . . motor housing, 12 . . . cover, 13 . . . socket part, 14 . . . connector body, 15 . . . end surface wall portion, 16S . . . power conversion circuit board, 17S . . . power supply circuit board, 18S . . . control circuit board, 19 . . . fixing screw, 20 . . . protruding fixing portion, 21A . . . board supporting body, 21B . . . board supporting body, 22 . . . terminal engaging hole, 23 . . . terminal engaging hole, 24 . . . fixing screw, 25 . . . terminal engaging hole, 26 . . . flexible connector, 27 . . . press-fitting type connector terminal, 28 . . . land portion, 29 . . . terminal engaging hole, 30 . . . insulating sheet, 31 . . . sharp-edged portion, 32 . . . elastic engaging portion, 33 . . . elastic engaging portion, 34 . . . press-fitting type connector terminal, 35 . . . bending fixing portion, 36 . . . sharp-edged portion, 37 . . . elastic engaging portion, 38 . . . elastic engaging portion

1. An electric drive device comprising:
an electric motor driving a mechanical control element;
a motor housing accommodating therein the electric motor; and
an electronic control unit provided at an end surface wall portion side of the motor housing which is an opposite side to an output portion of a rotation shaft of the electric motor and configured to drive the electric motor, wherein
the electronic control unit has:
a circuit board mounting thereon electronic components that forms the electronic control unit; and
a board supporting body located so as to be adjacent to the circuit board and supporting the circuit board; and
a press-fitting type connector terminal for fixing the circuit board and the board supporting body,
the circuit board is provided with a first terminal engaging hole, and the board supporting body located so as to be adjacent to the circuit board is provided with a second terminal engaging hole,
a first elastic engaging portion that is elastically engaged with the first terminal engaging hole, and a second elastic engaging portion that is elastically engaged with the second terminal engaging hole, are formed so as to be adjacent to each other at the press-fitting type connector terminal, and
the circuit board and the board supporting body are fixedly connected together with the first and second elastic engaging portions being elastically engaged with the first and second terminal engaging holes respectively in a state in which the press-fitting type connector terminal is inserted into the first and second terminal engaging holes.

2. The electric drive device as claimed in claim 1, wherein
the electronic control unit has a power supply circuit unit configured to generate power as a main function, a power conversion circuit unit configured to drive the electric motor as a main function and a control circuit unit configured to control the power conversion circuit unit as a main function, and
the control circuit unit is mounted on the circuit board, and the press-fitting type connector terminal is connected to an earth terminal of the control circuit unit.

3. The electric drive device as claimed in claim 2, wherein
the press-fitting type connector terminal is inserted from a circuit board side toward the board supporting body,
the second terminal engaging hole is formed to be smaller than the first terminal engaging hole, and
according to sizes of the first and second terminal engaging holes, the second elastic engaging portion of the press-fitting type connector terminal is formed to be smaller than the first elastic engaging portion.

4. An electric drive device comprising:
an electric motor driving a mechanical control element;
a motor housing accommodating therein the electric motor; and
an electronic control unit provided at an end surface wall portion side of the motor housing which is an opposite side to an output portion of a rotation shaft of the electric motor and configured to drive the electric motor, wherein
the electronic control unit has:
a circuit board mounting thereon electronic components that forms the electronic control unit;
a board supporting body supporting the circuit board; and
a press-fitting type connector terminal for fixing the board supporting body and a fixing portion that is formed at the end surface wall portion,
the board supporting body is structured to be fixed to the fixing portion,
the board supporting body supporting the circuit board is provided with a first terminal engaging hole, and the fixing portion located so as to be adjacent to the board supporting body is provided with a second terminal engaging hole,
a first elastic engaging portion that is elastically engaged with the first terminal engaging hole, and a second elastic engaging portion that is elastically engaged with the second terminal engaging hole, are formed at the press-fitting type connector terminal, and
the board supporting body and the fixing portion are fixedly connected together with the first and second elastic engaging portions being elastically engaged with the first and second terminal engaging holes respectively in a state in which the press-fitting type connector terminal is inserted into the first and second terminal engaging holes.

5. The electric drive device as claimed in claim 4, wherein
the press-fitting type connector terminal is inserted from a board supporting body side toward the fixing portion,
the second terminal engaging hole is formed to be smaller than the first terminal engaging hole, and
according to sizes of the first and second terminal engaging holes, the second elastic engaging portion of the press-fitting type connector terminal is formed to be smaller than the first elastic engaging portion.

6. An electric drive device comprising:
an electric motor driving a mechanical control element;
a motor housing accommodating therein the electric motor; and
an electronic control unit provided at an end surface wall portion side of the motor housing which is an opposite side to an output portion of a rotation shaft of the electric motor and configured to drive the electric motor, wherein
the electronic control unit has:
a circuit board mounting thereon electronic components that forms the electronic control unit;
a board supporting body located so as to be adjacent to the circuit board and supporting the circuit board;
a first press-fitting type connector terminal for fixing the circuit board and the board supporting body; and
a second press-fitting type connector terminal for fixing the board supporting body and a fixing portion that is formed at the end surface wall portion,
the circuit board is provided with a first terminal engaging hole, and the board supporting body located so as to be adjacent to the circuit board is provided with a second terminal engaging hole,
a first elastic engaging portion that is elastically engaged with the first terminal engaging hole, and a second elastic engaging portion that is elastically engaged with the second terminal engaging hole, are formed so as to be adjacent to each other at the first press-fitting type connector terminal,
the circuit board and the board supporting body are fixedly connected together with the first and second elastic engaging portions being elastically engaged with the first and second terminal engaging holes respectively in a state in which the first press-fitting type connector terminal is inserted into the first and second terminal engaging holes,
the board supporting body supporting the circuit board is provided with a third terminal engaging hole, and the fixing portion located so as to be adjacent to the board supporting body is provided with a fourth terminal engaging hole,
a third elastic engaging portion that is elastically engaged with the third terminal engaging hole, and a fourth elastic engaging portion that is elastically engaged with the fourth terminal engaging hole, are formed at the second press-fitting type connector terminal,
the board supporting body and the fixing portion are fixedly connected together with the third and fourth elastic engaging portions being elastically engaged with the third and fourth terminal engaging holes respectively in a state in which the second press-fitting type connector terminal is inserted into the third and fourth terminal engaging holes, and
the first press-fitting type connector terminal and the second press-fitting type connector terminal are electrically connected to each other.

7. The electric drive device as claimed in claim 6, wherein
the electronic control unit has a power supply circuit unit configured to generate power as a main function, a power conversion circuit unit configured to drive the electric motor as a main function and a control circuit unit configured to control the power conversion circuit unit as a main function,
the control circuit unit is mounted on the circuit board, and the first elastic engaging portion of the first press-fitting type connector terminal is connected to an earth terminal of the control circuit unit, and
the earth terminal of the control circuit unit forms an earth circuit with the earth terminal being connected to the fixing portion from the first elastic engaging portion of the first press-fitting type connector terminal through the fourth elastic engaging portion of the second press-fitting type connector terminal.

8. The electric drive device as claimed in claim 7, wherein
the first press-fitting type connector terminal is inserted from a circuit board side toward the board supporting body,
the second terminal engaging hole is formed to be smaller than the first terminal engaging hole,
according to sizes of the first and second terminal engaging holes, the second elastic engaging portion of the first press-fitting type connector terminal is formed to be smaller than the first elastic engaging portion,
the second press-fitting type connector terminal is inserted from a board supporting body side toward the fixing portion,
the fourth terminal engaging hole is formed to be smaller than the third terminal engaging hole, and
according to sizes of the third and fourth terminal engaging holes, the fourth elastic engaging portion of the second press-fitting type connector terminal is formed to be smaller than the third elastic engaging portion.

9. An electric power steering device comprising:
an electric motor providing a steering assistive force to a steering shaft on the basis of an output from a torque sensor that detects a turning direction and a turning torque of the steering shaft;
a motor housing accommodating therein the electric motor;
an electronic control unit provided at an end surface wall portion side of the motor housing which is an opposite side to an output portion of a rotation shaft of the electric motor and configured to drive the electric motor; and
a cover covering the electronic control unit, wherein
the electronic control unit has:
a circuit board mounting thereon electronic components that forms the electronic control unit;
a board supporting body located so as to be adjacent to the circuit board and supporting the circuit board; and
a press-fitting type connector terminal for fixing the circuit board and the board supporting body,
the circuit board is provided with a first terminal engaging hole, and the board supporting body located so as to be adjacent to the circuit board is provided with a second terminal engaging hole,
a first elastic engaging portion that is elastically engaged with the first terminal engaging hole, and a second elastic engaging portion that is elastically engaged with the second terminal engaging hole, are formed so as to be adjacent to each other at the press-fitting type connector terminal, and
the circuit board and the board supporting body are fixedly connected together with the first and second elastic engaging portions being elastically engaged with the first and second terminal engaging holes respectively in a state in which the press-fitting type connector terminal is inserted into the first and second terminal engaging holes.

10. The electric power steering device as claimed in claim 9, wherein
the electronic control unit has a power supply circuit unit configured to generate power as a main function, a power conversion circuit unit configured to drive the electric motor as a main function and a control circuit unit configured to control the power conversion circuit unit as a main function, and
the control circuit unit is mounted on the circuit board, and the press-fitting type connector terminal is connected to an earth terminal of the control circuit unit.

11. The electric power steering device as claimed in claim 10, wherein
the press-fitting type connector terminal is inserted from a circuit board side toward the board supporting body,
the second terminal engaging hole is formed to be smaller than the first terminal engaging hole, and
according to sizes of the first and second terminal engaging holes, the second elastic engaging portion of the press-fitting type connector terminal is formed to be smaller than the first elastic engaging portion.

12. An electric power steering device comprising:
an electric motor providing a steering assistive force to a steering shaft on the basis of an output from a torque sensor that detects a turning direction and a turning torque of the steering shaft;
a motor housing accommodating therein the electric motor;
an electronic control unit provided at an end surface wall portion side of the motor housing which is an opposite side to an output portion of a rotation shaft of the electric motor and configured to drive the electric motor; and
a cover covering the electronic control unit, wherein
the electronic control unit has:
a circuit board mounting thereon electronic components that forms the electronic control unit;
a board supporting body supporting the circuit board; and
a press-fitting type connector terminal for fixing the board supporting body and a fixing portion that is formed at the end surface wall portion,
the board supporting body is structured to be fixed to the fixing portion,
the board supporting body supporting the circuit board is provided with a first terminal engaging hole, and the fixing portion located so as to be adjacent to the board supporting body is provided with a second terminal engaging hole,
a first elastic engaging portion that is elastically engaged with the first terminal engaging hole, and a second elastic engaging portion that is elastically engaged with the second terminal engaging hole, are formed at the press-fitting type connector terminal, and
the board supporting body and the fixing portion are fixedly connected together with the first and second elastic engaging portions being elastically engaged with the first and second terminal engaging holes respectively in a state in which the press-fitting type connector terminal is inserted into the first and second terminal engaging holes.

13. The electric power steering device as claimed in claim 12, wherein
the press-fitting type connector terminal is inserted from a board supporting body side toward the fixing portion,
the second terminal engaging hole is formed to be smaller than the first terminal engaging hole, and
according to sizes of the first and second terminal engaging holes, the second elastic engaging portion of the press-fitting type connector terminal is formed to be smaller than the first elastic engaging portion.

14. An electric power steering device comprising:
an electric motor providing a steering assistive force to a steering shaft on the basis of an output from a torque sensor that detects a turning direction and a turning torque of the steering shaft;
a motor housing accommodating therein the electric motor;
an electronic control unit provided at an end surface wall portion side of the motor housing which is an opposite side to an output portion of a rotation shaft of the electric motor and configured to drive the electric motor; and
a cover covering the electronic control unit, wherein
the electronic control unit has:
a circuit board mounting thereon electronic components that forms the electronic control unit;
a board supporting body located so as to be adjacent to the circuit board and supporting the circuit board;
a first press-fitting type connector terminal for fixing the circuit board and the board supporting body; and
a second press-fitting type connector terminal for fixing the board supporting body and a fixing portion that is formed at the end surface wall portion,
the circuit board is provided with a first terminal engaging hole, and the board supporting body located so as to be adjacent to the circuit board is provided with a second terminal engaging hole,
a first elastic engaging portion that is elastically engaged with the first terminal engaging hole, and a second elastic engaging portion that is elastically engaged with the second terminal engaging hole, are formed so as to be adjacent to each other at the first press-fitting type connector terminal,
the circuit board and the board supporting body are fixedly connected together with the first and second elastic engaging portions being elastically engaged with the first and second terminal engaging holes respectively in a state in which the first press-fitting type connector terminal is inserted into the first and second terminal engaging holes,
the board supporting body supporting the circuit board is provided with a third terminal engaging hole, and the fixing portion located so as to be adjacent to the board supporting body is provided with a fourth terminal engaging hole,
a third elastic engaging portion that is elastically engaged with the third terminal engaging hole, and a fourth elastic engaging portion that is elastically engaged with the fourth terminal engaging hole, are formed at the second press-fitting type connector terminal,
the board supporting body and the fixing portion are fixedly connected together with the third and fourth elastic engaging portions being elastically engaged with the third and fourth terminal engaging holes respectively in a state in which the second press-fitting type connector terminal is inserted into the third and fourth terminal engaging holes, and
the first press-fitting type connector terminal and the second press-fitting type connector terminal are electrically connected to each other.

15. The electric power steering device as claimed in claim 14, wherein
the electronic control unit has a power supply circuit unit configured to generate power as a main function, a power conversion circuit unit configured to drive the electric motor as a main function and a control circuit unit configured to control the power conversion circuit unit as a main function,
the control circuit unit is mounted on the circuit board, and the first elastic engaging portion of the first press-fitting type connector terminal is connected to an earth terminal of the control circuit unit, and
the earth terminal of the control circuit unit forms an earth circuit with the earth terminal being connected to the fixing portion from the first elastic engaging portion of the first press-fitting type connector terminal through the fourth elastic engaging portion of the second press-fitting type connector terminal.

16. The electric power steering device as claimed in claim 15, wherein
the first press-fitting type connector terminal is inserted from a circuit board side toward the board supporting body,
the second terminal engaging hole is formed to be smaller than the first terminal engaging hole,
according to sizes of the first and second terminal engaging holes, the second elastic engaging portion of the first press-fitting type connector terminal is formed to be smaller than the first elastic engaging portion,
the second press-fitting type connector terminal is inserted from a board supporting body side toward the fixing portion,
the fourth terminal engaging hole is formed to be smaller than the third terminal engaging hole, and
according to sizes of the third and fourth terminal engaging holes, the fourth elastic engaging portion of the second press-fitting type connector terminal is formed to be smaller than the third elastic engaging portion.
